(19) United States
(12) Patent Application Publication
(10) Pub. No.: US 2025/0072023 A1
(43) Pub. Date: Feb. 27, 2025

(54) SEMICONDUCTOR DEVICE

(71) Applicant: Mitsubishi Electric Corporation, Tokyo (JP)

(72) Inventors: Kazuya KONISHI, Tokyo (JP); Atsufumi INOUE, Tokyo (JP); Munetaka NOGUCHI, Tokyo (JP); Tomohiro TAMAKI, Tokyo (JP); Kohei ONDA, Tokyo (JP)

(73) Assignee: Mitsubishi Electric Corporation, Tokyo (JP)

(21) Appl. No.: 18/441,094

(22) Filed: Feb. 14, 2024

(30) Foreign Application Priority Data
Aug. 23, 2023 (JP) 2023-135870

(51) Int. Cl. H01L 29/739; H01L 29/06; H01L 29/10; H01L 29/423

(52) U.S. Cl. CPC H01L 29/7397; H01L 27/0727; H01L 29/1095; H01L 29/4236

(57) ABSTRACT

A trench in a first region includes a first trench, and two or more second trenches that sandwich the first trench from both sides. The gate electrodes formed in the two or more second trenches are connected to each other and are not connected to the gate electrode formed in the first trench. The gate electrode formed in the trench in the second region is connected to the emitter electrode. The base layer is connected to the emitter electrode in a region between the first region and the second region.

### BACKGROUND OF THE INVENTION

### Field

The present disclosure relates to a semiconductor device.

### Background

There has been proposed a semiconductor device that reduces a turn-on loss by a macro thinning structure in which a first region in which three or more active trenches are arranged and a second region in which a plurality of dummy trenches are arranged are alternately provided (see, for example, Patent Literature 1).

### CITATION LIST

### Patent Literature

Patent Literature 1: JP 6743026 B2

### SUMMARY

### Technical Problem

In a semiconductor device having a macro thinning structure in related art, there is a problem that a loss cannot be sufficiently reduced because multigate driving is not taken into account.

The present disclosure has been made to solve the problem as described above, and an object thereof is to provide a semiconductor device capable of sufficiently reducing a loss.

### Solution to Problem

A semiconductor device according to the present disclosure includes: a semiconductor substrate of a first conductive type having a first region and a second region which are adjacent to each other; a base layer of a second conductive type formed on an upper surface side of the semiconductor substrate; a source layer of the first conductive type formed on an upper surface side of the base layer; a plurality of gate electrodes respectively formed via gate insulator films inside a plurality of trenches penetrating the source layer and the base layer from the upper surface side of the semiconductor substrate; an emitter electrode formed on the upper surface of the semiconductor substrate; a collector layer of the second conductive type formed on a lower surface side of the semiconductor substrate; and a collector electrode formed on the lower surface of the semiconductor substrate, wherein the trench in the first region includes a first trench, and two or more second trenches that sandwich the first trench from both sides, the gate electrodes formed in the two or more second trenches are connected to each other and are not connected to the gate electrode formed in the first trench, the gate electrode formed in the trench in the second region is connected to the emitter electrode, and the base layer is connected to the emitter electrode in a region between the first region and the second region.

### Advantageous Effects of Invention

In the present disclosure, two or more second trenches are formed so as to sandwich the first trench from both sides in the first region having a macro thinning structure. The gate electrodes formed in the two or more second trenches are connected to each other and are not connected to the gate electrode formed in the first trench. In a region between the first region and the second region, the base layer is connected to the emitter electrode. For example, by turning off the gate electrodes in the second trenches at a timing earlier than a timing for the gate electrode in the first trench in turn-off, holes flowing from a portion below the second region to a portion below the first region can be discharged to the emitter electrode through sides of the second trenches, so that it is possible to reduce a turn-off loss. As a result of this, it is possible to sufficiently reduce a loss.

### BRIEF DESCRIPTION OF DRAWINGS

FIG. 1 is a cross-sectional view illustrating a semiconductor device according to a first embodiment.

FIG. 2 is a view illustrating driving of the semiconductor device according to the first embodiment.

FIG. 3 is a cross-sectional view illustrating a first modification of the semiconductor device according to the first embodiment.

FIG. 4 is a cross-sectional view illustrating a second modification of the semiconductor device according to the first embodiment.

FIG. 5 is a cross-sectional view illustrating a third modification of the semiconductor device according to the first embodiment.

FIG. 6 is a cross-sectional view illustrating a fourth modification of the semiconductor device according to the first embodiment.

FIG. 7 is a cross-sectional view illustrating a semiconductor device according to a second embodiment.

FIG. 8 is a cross-sectional view illustrating a modification of the semiconductor device according to the second embodiment.

FIG. 9 is a cross-sectional view illustrating a semiconductor device according to a third embodiment.

FIG. 10 is a cross-sectional view illustrating a first modification of the semiconductor device according to the third embodiment.

FIG. 11 is a cross-sectional view illustrating a second modification of the semiconductor device according to the third embodiment.

FIG. 12 is a cross-sectional view illustrating a third modification of the semiconductor device according to the third embodiment.

FIG. 13 is a cross-sectional view illustrating a fourth modification of the semiconductor device according to the third embodiment.

FIG. 14 is a cross-sectional view illustrating a fifth modification of the semiconductor device according to the third embodiment.

FIG. 15 is a cross-sectional view illustrating a semiconductor device according to a fourth embodiment.

FIG. 16 is a cross-sectional view illustrating a modification of the semiconductor device according to the fourth embodiment.

FIG. 17 is a cross-sectional view illustrating a semiconductor device according to a fifth embodiment.

FIG. 18 is a cross-sectional view illustrating a modification of the semiconductor device according to the fifth embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

In the following description, n and p indicate conductive types of a semiconductor, a first conductive type is described as an n type, and a second conductive type is described as a p type. However, the first conductive type may be a p type, and the second conductive type may be an n type. Further, n indicates that its impurity concentration is lower than that of n, and n⁺ indicates that its impurity concentration is higher than that of n. In a similar manner, p⁺ indicates that its impurity concentration is higher than that of p. Note that features of semiconductor devices according to embodiments may be combined as appropriate to enhance effects of the present invention.

### First Embodiment

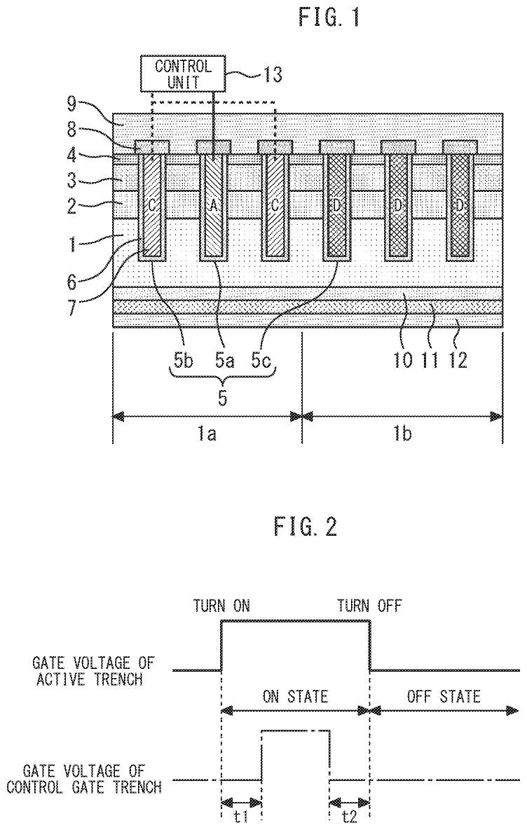

FIG. 1 is a cross-sectional view illustrating a semiconductor device according to a first embodiment. This semiconductor device is an insulated gate bipolar transistor (hereinafter, abbreviated as IGBT).

A semiconductor substrate 1 constitutes an n⁻-type drift layer. An n-type impurity of the semiconductor substrate 1 is, for example, arsenic, phosphorous, or the like. The concentration of the n-type impurity of the semiconductor substrate 1 is 1.0E+12/cm³ to 1.0E+15/cm³. The semiconductor substrate 1 has a first region 1a and a second region 1b which are adjacent to each other.

An n-type carrier accumulation layer 2 is formed on an upper surface side of the n⁻-type drift layer of the semiconductor substrate 1. An n-type impurity of the n-type carrier accumulation layer 2 is, for example, arsenic, phosphorous, or the like. The concentration of the n-type impurity of the n-type carrier accumulation layer 2 is 1.0E+13/cm³ to 1.0E+17/cm³. Formation of the n-type carrier accumulation layer 2 can reduce a conduction loss when a current flows. Note that it is also possible to employ a configuration where the n-type carrier accumulation layer 2 is not formed and the n⁻-type drift layer is provided also in the region corresponding to the n-type carrier accumulation layer 2. The n-type carrier accumulation layer 2 and the n⁻-type drift layer may be collectively referred to as a drift layer.

A p-type base layer 3 is formed on an upper surface side of the n-type carrier accumulation layer 2. In other words, the n-type carrier accumulation layer 2 is formed below the p-type base layer 3. A p-type impurity of the p-type base layer 3 is, for example, boron, aluminum, or the like. The impurity concentration of the p-type base layer 3 is 1.0E+12/cm³ to 1.0E+19/cm^{3.} An n⁺-type source layer 4 is formed on an upper surface side of the p-type base layer 3. An n-type impurity of the n⁺-type source layer 4 is, for example, arsenic, phosphorous, or the like. The impurity concentration of the n⁺-type source layer 4 is 1.0E+17/cm³ to 1.0E+20/cm³.

A plurality of trenches 5 are formed so as to penetrate the n⁺-type source layer 4, the p-type base layer 3 and the n-type carrier accumulation layer 2 from the upper surface side of the semiconductor substrate 1 and reach the n⁻-type drift layer. Gate insulator films 6 are formed along inner walls of the trenches 5. A plurality of gate electrodes 7 are respectively formed inside the plurality of trenches 5 via the gate insulator films 6. The gate electrode 7 faces the n⁺-type source layer 4, the p-type base layer 3, the n-type carrier accumulation layer 2 and the n⁻-type drift layer via the gate insulator films 6.

The n⁺-type source layers 4 and p⁺-type contact layers (not illustrated) are alternately formed along the extending direction of the trenches 5. The n⁺-type source layers 4 and the p⁺-type contact layers constitute the upper surface of the semiconductor substrate 1. A p-type impurity of the p⁺-type contact layer is, for example, boron, aluminum, or the like. The concentration of the p-type impurity of the p⁺-type contact layer is higher than that of the p-type base layer 3 and is 1.0E+15/cm³ to 1.0E+20/cm³. In a case where it is necessary to distinguish between the p⁺-type contact layer and the p-type base layer 3, they may be individually referred to, or the p⁺-type contact layer and the p-type base layer 3 may be collectively referred to as a p-type base layer.

Interlayer dielectric films 8 are formed on the trenches 5. While not illustrated, a barrier metal is formed on a region where the interlayer dielectric film 8 is not formed on the upper surface of the semiconductor substrate 1 and on the interlayer dielectric films 8. The barrier metal is a conductor containing titanium (Ti) and, for example, titanium nitride or TiSi obtained by alloying titanium and silicon (Si). The barrier metal is in ohmic contact with the n⁺-type source layer 4 and the p⁺-type contact layer and is electrically connected to the n⁺-type source layer 4 and the p⁺-type contact layer. An emitter electrode 9 is formed on the upper surface of the semiconductor substrate 1 and is connected to the barrier metal. The emitter electrode 9 is, for example, an aluminum alloy such as an aluminum silicon alloy (Al-Si alloy) and may be an electrode including a plurality of layers of metal films obtained by forming a plating film through electroless plating or electrolytic plating on the electrode formed with an aluminum alloy. The plating film to be formed through electroless plating or electrolytic plating is, for example, a nickel (Ni) plating film. In a case where favorable embedding cannot be implemented in a minute region between adjacent interlayer dielectric films 8 with the emitter electrode 9, tungsten having more favorable embeddability than the emitter electrode 9 may be formed in the minute region, and the emitter electrode 9 may be formed on tungsten. Note that the emitter electrode 9 may be formed on the n⁺-type source layer 4 and the p⁺-type contact layer without the barrier metal being formed. The barrier metal may be formed only on n-type semiconductor layers such as the n⁺-type source layers 4. The barrier metal and the emitter electrode 9 may be collectively referred to as an emitter electrode.

An n-type buffer layer 10 is formed on a lower surface side of the n⁻-type drift layer of the semiconductor substrate 1. An n-type impurity of the n-type buffer layer 10 is, for example, one or both of phosphorus (P) and protons (H+). The concentration of the n-type impurity of the n-type buffer layer 10 is higher than that of the n⁻-type drift layer and is 1.0E+12/cm³ to 1.0E+18/cm³. The n-type buffer layer 10 is provided to prevent a depletion layer extending to the lower surface side from the p-type base layer 3 from punching through when the semiconductor device is in an OFF state. Note that it is also possible to employ a configuration where the n-type buffer layer 10 is not formed and the n⁻-type drift layer is provided also in a region corresponding to the n-type buffer layer 10. The n-type buffer layer 10 and the n⁻-type drift layer may be collectively referred to as a drift layer.

A p-type collector layer 11 is formed on a lower surface side of the n-type buffer layer 10. In other words, the p-type collector layer 11 is formed between the n⁻-type drift layer and the lower surface of the semiconductor substrate 1. A p-type impurity of the p-type collector layer 11 is, for example, boron, aluminum, or the like. The impurity concentration of the p-type collector layer 11 is 1.0E+16/cm³ to 1.0E+20/cm³. The semiconductor substrate 1 includes the range from the n⁺-type source layer 4 and the p⁺-type contact layer to the p-type collector layer 11.

The collector electrode 12 is formed on the lower surface of the semiconductor substrate 1. The collector electrode 12 is formed with an aluminum alloy, or an aluminum alloy and a plating film in a similar manner to the emitter electrode 9. The collector electrode 12 may have a configuration different from that of the emitter electrode 9. The collector electrode 12 is in ohmic contact with the p-type collector layer 11 and is electrically connected to the p-type collector layer 11.

In the first region 1a, three or more trenches 5 are formed. In the present embodiment, the trenches 5 in the first region 1a include an active trench 5a, and two or more control gate trenches 5b that sandwich the active trench 5a from both sides. The gate electrodes 7 formed in the two or more control gate trenches 5b are connected to each other and are not connected to the gate electrode 7 formed in the active trench 5a.

In the second region 1b, one or more trenches 5 are formed. The trenches 5 in the second region 1b are dummy trenches 5c. The gate electrodes 7 formed in the dummy trenches 5c are connected to the emitter electrode 9. In a region between the first region 1a and the second region 1b, the p-type base layer 3 is connected to the emitter electrode 9.

The gate insulator film 6 in the active trench 5a is in contact with the p-type base layer 3 and the n⁺-type source layer 4. When a gate drive voltage is applied to the gate electrode 7 in the active trench 5a, a channel is formed to the p-type base layer 3 that is in contact with the gate insulator film 6 in the active trench 5a. The n⁺-type source layer 4 only requires to be in contact with the active trench 5a and does not have to be in contact with the dummy trenches 5c. Thus, the n⁺-type source layer 4 does not have to be formed in a region between the dummy trenches 5c.

FIG. 2 is a view illustrating driving of the semiconductor device according to the first embodiment. In turn-on of the IGBT, a control unit 13 turns on the gate electrodes 7 in the control gate trenches 5b at a timing later by a period t1 than a timing for the gate electrode 7 in the active trench 5a. In turn-off of the IGBT, the control unit 13 turns off the gate electrodes 7 in the control gate trenches 5b at a timing earlier by a period t2 than a timing for the gate electrode 7 in the active trench 5a.

Next, a method for manufacturing the semiconductor device according to the first embodiment will be described. First, the semiconductor substrate 1 constituting the n⁻-type drift layer is prepared. As the semiconductor substrate 1, for example, an FZ wafer manufactured using a floating zone (FZ) method or an MCZ wafer manufactured using a magnetic applied CZochralki (MCZ) method is used. An n-type wafer including an n-type impurity may be used as the semiconductor substrate 1. The concentration of the n-type impurity included in the semiconductor substrate 1 is selected as appropriate in accordance with a withstand voltage of the semiconductor device to be manufactured. For example, in a semiconductor device having the withstand voltage of 1200 V, the concentration of the n-type impurity of the semiconductor substrate 1 is adjusted so that specific resistance of the n⁻-type drift layer becomes approximately 40 to 120 Ω·cm. Note that the whole of the semiconductor substrate 1 is the n⁻-type drift layer in a step of preparing the semiconductor substrate 1. A p-type or n-type semiconductor layer is formed by implanting p-type or n-type impurity ions from an upper surface side or a lower surface side of such a semiconductor substrate 1 and then diffusing the impurity ions within the semiconductor substrate 1 through thermal treatment, or the like.

Then, the n-type carrier accumulation layer 2 is formed by implanting an n-type impurity such as phosphorus (P) from the upper surface side of the semiconductor substrate 1 and diffusing the n-type impurity in the n⁻-type drift layer. Further, the p-type base layer 3 is formed by implanting a p-type impurity such as boron (B) from the upper surface side of the semiconductor substrate 1. The n-type carrier accumulation layer 2 and the p-type base layer 3 are formed by implanting impurity ions to the semiconductor substrate 1 and then diffusing the impurity ions through thermal treatment. The n-type impurity ions and the p-type impurity ions are implanted after the upper surface of the semiconductor substrate 1 is subjected to mask processing, and thus, the n-type carrier accumulation layer 2 and the p-type base layer 3 are selectively formed on the upper surface side of the semiconductor substrate 1. Note that the mask processing is processing of forming a mask by applying resist on the upper surface of the semiconductor substrate 1 and forming openings in a predetermined region of the resist using a photoengraving technique. The ions are implanted or etching is performed in the predetermined region of the semiconductor substrate 1 via the openings of the mask.

Then, the n⁺-type source layer 4 is formed by selectively implanting the n-type impurity on the upper surface side of the p-type base layer 3 through mask processing. The n-type impurity to be implanted is, for example, arsenic (As) or phosphorus (P). Further, the p⁺-type contact layer is formed by selectively implanting the p-type impurity on the upper surface side of the p-type base layer 3 through mask processing. The p-type impurity to be implanted is, for example, boron (B) or aluminum (Al).

Then, after an oxide film such as SiO₂ is deposited on the upper surface of the semiconductor substrate 1, openings are formed in the oxide film through the mask processing at portions where the trenches 5 are to be formed. The trenches 5 are formed by etching the semiconductor substrate 1 using the oxide film in which the openings are formed as a mask. The trenches 5 penetrate the p-type base layer 3 and the n⁺-type source layer 4 from the upper surface side of the semiconductor substrate 1 and reach the n⁻-type drift layer. Side walls of the trenches 5 that penetrate the n⁺-type source layer 4 constitute part of the n⁺-type source layer 4.

Then, the gate insulator films 6 are formed on the inner walls of the trenches 5 and the upper surface of the semiconductor substrate 1 by heating the semiconductor substrate 1 in an atmosphere including oxygen. The gate electrodes 7 are formed by depositing n-type or p-type-impurity-doped polysilicon within the trenches 5 in which the gate insulator films 6 are formed on the inner walls, through chemical vapor deposition (CVD), or the like.

Then, after the interlayer dielectric films 8 are formed on the trenches 5, the gate insulator film 6 formed on the upper surface of the semiconductor substrate 1 is removed. The interlayer dielectric films 8 are, for example, SiO₂. Contact holes are formed in the interlayer dielectric films 8 above the n⁺-type source layer 4 and the p⁺-type contact layer through mask processing.

Then, a barrier metal is formed on the upper surface of the semiconductor substrate 1 and the interlayer dielectric films 8. The emitter electrode 9 is formed on the barrier metal. For example, the barrier metal is formed by forming a film of titanium nitride through physical vapor deposition (PVD) or CVD. For example, the emitter electrode 9 is formed by depositing an aluminum silicon alloy (Al-Si alloy) on the barrier metal through PVD such as sputtering or vapor deposition. Further, a nickel alloy (Ni alloy) is further formed on the formed aluminum silicon alloy through electroless plating or electrolytic plating to form the emitter electrode 9. A thick metal film can be easily formed as the emitter electrode 9 through plating, so that it is possible to increase heat capacity of the emitter electrode 9 and improve heat resistance of the emitter electrode 9.

Then, the lower surface side of the semiconductor substrate 1 is ground to be thinner until the semiconductor substrate 1 has a predetermined thickness. The thickness of the ground semiconductor substrate 1 is, for example, 80 μm to 200 μm. In a case where a nickel alloy is further formed through plating processing after the emitter electrode 9 formed with an aluminum silicon alloy is formed through the PVD, the plating processing for forming the nickel alloy may be performed after processing is performed on the lower surface side of the semiconductor substrate 1.

Then, the n-type buffer layer 10 is formed by implanting an n-type impurity from the lower surface side of the semiconductor substrate 1. For example, the n-type buffer layer 10 is formed by implanting phosphorus (P) ions or protons (H⁺). Both of protons and phosphorus may be implanted to form the n-type buffer layer 10. Protons can be implanted to deep positions from the lower surface of the semiconductor substrate 1 with relatively low acceleration energy. By changing the acceleration energy, depth to which protons are to be implanted can be relatively easily changed. Thus, when the n-type buffer layer 10 is formed with protons, by implanting protons a plurality of times while changing the acceleration energy, it is possible to form the n-type buffer layer 10 having a wider width in a thickness direction of the semiconductor substrate 1 than a case where the n-type buffer layer 10 is formed with phosphorus. On the other hand, phosphorus can increase its activation rate as an n-type impurity compared to protons. It is therefore possible to more reliably prevent a depletion layer from punching through by forming the n-type buffer layer 10 with phosphorus, even with the semiconductor substrate 1 being made thinner. To make the semiconductor substrate 1 further thinner, it is preferable to form the n-type buffer layer 10 by implanting both protons and phosphorus. In this case, protons are implanted to deeper positions from the lower surface than phosphorus.

Then, the p-type collector layer 11 is formed by implanting a p-type impurity from the lower surface side of the semiconductor substrate 1. For example, the p-type collector layer 11 is formed by implanting boron (B). By implanting ions from the lower surface side of the semiconductor substrate 1 and then irradiating the lower surface with laser to perform laser annealing, the implanted boron is activated, and the p-type collector layer 11 is formed. In this event, phosphorus for the n-type buffer layer 10 implanted at a relatively shallow position from the lower surface of the semiconductor substrate 1 is also activated at the same time. On the other hand, protons are activated at a relatively low anneal temperature of 350° C. to 500° C., and thus, it is necessary to ensure that the whole of the semiconductor substrate 1 does not become a temperature higher than 350° C. to 500° C. other than a step for activating protons after protons are implanted. In laser annealing, only a temperature of a portion in the vicinity of the lower surface of the semiconductor substrate 1 can be made higher, and thus laser annealing can be used in activation of the n-type impurity or the p-type impurity even after protons are implanted.

Then, the collector electrode 12 is formed on the lower surface of the semiconductor substrate 1. The collector electrode 12 may be formed over the whole lower surface of an n-type wafter that is the semiconductor substrate 1. While the collector electrode 12 is formed by depositing an aluminum silicon alloy (Al-Si alloy), titanium (Ti), or the like, through PVD such as sputtering or vapor deposition, the collector electrode 12 may be formed by layering a plurality of metals such as an aluminum silicon alloy, titanium, nickel and gold. The collector electrode 12 may be formed by further forming a metal film on the metal film formed through PVD, through electroless plating or electrolytic plating.

The semiconductor device according to the present embodiment is manufactured through the steps described above. A plurality of semiconductor devices are manufactured on one n-type wafer in a matrix. Thus, the semiconductor devices are completed by cutting the wafer into individual semiconductor devices through laser dicing or blade dicing.

As described above, the semiconductor device according to the present embodiment has a macro thinning structure in which a first region 1a in which three or more trenches 5 including an active trench 5a are formed and a second region 1b in which one or more dummy trenches 5c are formed are adjacent to each other. With such a macro thinning structure, a turn-on loss can be reduced. However, holes below the second region 1b into which electrons are not injected flow to a portion below the first region 1a into which electrons are injected, which causes bias in hole density in a lateral direction and incurs increase of a turn-off loss. Thus, in the present embodiment, two or more control gate trenches 5b are formed so as to sandwich the active trench 5a from both sides in the first region 1a. Further, the p-type base layer 3 is connected to the emitter electrode 9 in a region between the first region 1a and the second region 1b. By turning off the gate electrodes 7 in the control gate trenches 5b at a timing earlier than a timing for the gate electrode 7 in the active trench 5a in turn-off, holes flowing from a portion below the second region 1b to a portion below the first region 1a can be discharged to the emitter electrode 9 through sides of the control gate trenches 5b, so that it is possible to reduce a turn-off loss. As a result of this, it is possible to sufficiently reduce a loss.

Further, the control unit 13 turns on the gate electrodes 7 in the control gate trenches 5b at a timing later than a timing for the gate electrode 7 in the active trench 5a in turn-on of the IGBT. Thus, the gate electrode 7 in the active trench 5a is turned on earlier, so that it is possible to shorten a charging period of gate capacitance necessary for turn-on and turn on the gate electrode 7 at high speed. This makes it possible to further reduce a turn-on loss. Note that the control unit 13 may perform only one of the control upon turn-off and the control upon turn-on described above.

Further, forming of the n-type carrier accumulation layer 2 below the p-type base layer 3 can facilitate electron injection, enhance a hole accumulation effect, and thereby reduce an ON voltage. However, this further increases bias of the hole density in the macro thinning structure and increases a turn-off loss. In contrast, in the present embodiment, holes flowing from a portion below the second region 1b to a portion below the first region 1a can be discharged to the emitter electrode 9 through sides of the control gate trenches 5b, so that it is possible to reduce a turn-off loss. It is therefore possible to reduce a turn-off loss while reducing an ON voltage.

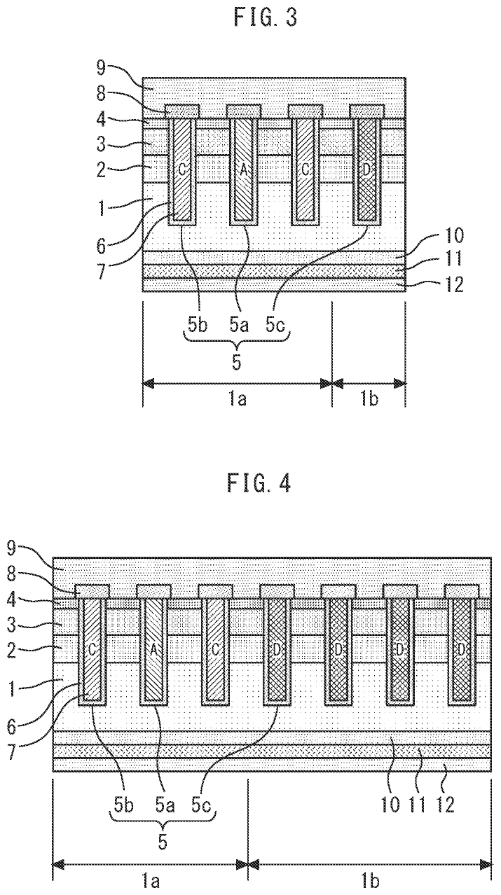

FIG. 3 is a cross-sectional view illustrating a first modification of the semiconductor device according to the first embodiment. The second region 1b includes one dummy trench 5c, which is less than three trenches 5 included in the first region 1a. FIG. 4 is a cross-sectional view illustrating a second modification of the semiconductor device according to the first embodiment. The second region 1b includes four trenches 5 which are more than three trenches 5 included in the first region 1a. In this manner, the number of the dummy trenches 5c included in the second region 1b is preferably equal to or larger than the number of the trenches 5 included in the first region 1a. This enhances an effect of reducing capacitance between the gate and the emitter which is a characteristic of the macro thinning structure, so that it is possible to reduce a turn-on loss. Further, an amount of holes flowing from a portion below the second region 1b to a portion below the first region 1a increases, and holes corresponding to the increased amount are discharged to the emitter electrode 9, thereby a turn-on loss can be further reduced.

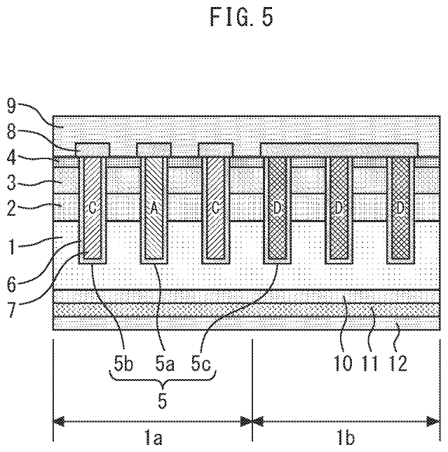

FIG. 5 is a cross-sectional view illustrating a third modification of the semiconductor device according to the first embodiment. The interlayer dielectric film 8 is formed over the second region 1b. Thus, the p-type base layer 3 sandwiched between the dummy trenches 5c in the second region 1b is not connected to the emitter electrode 9. By this means, an amount of holes flowing from a portion below the second region 1b to a portion below the first region 1a increases, and holes corresponding to the increased amount are discharged to the emitter electrode 9, thereby a turn-on loss can be further reduced.

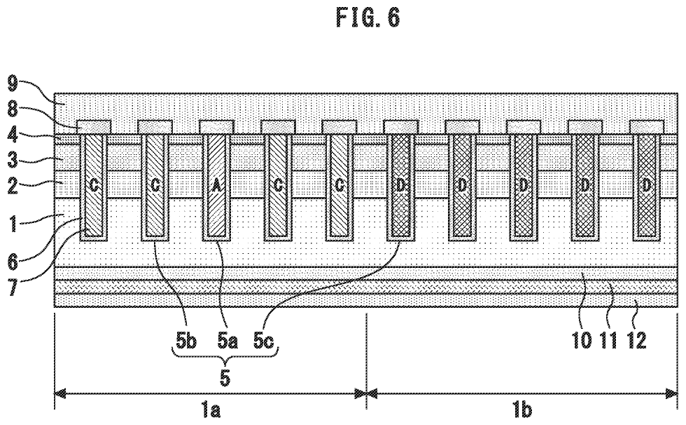

FIG. 6 is a cross-sectional view illustrating a fourth modification of the semiconductor device according to the first embodiment. In the first region 1a, the number of the control gate trenches 5b is three times or more of the number of the active trenches Sa. This further enhances an effect of discharging holes from the control gate trenches 5b, so that it is possible to further reduce a turn-off loss.

### Second Embodiment

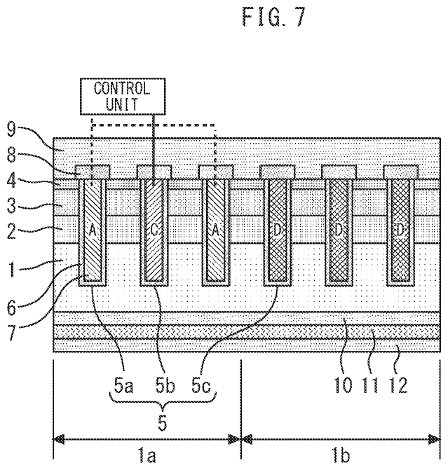

FIG. 7 is a cross-sectional view illustrating a semiconductor device according to a second embodiment. In the present embodiment, the trenches 5 in the first region 1a include the control gate trench 5b and two or more active trenches 5a that sandwich the control gate trench 5b from both sides.

The control unit 13 turns off the gate electrodes 7 in the active trenches 5a at a timing later than a timing for the gate electrode 7 in the control gate trench 5b in turn-off. Thus, electrons are not injected from the control gate trench 5b in turn-off, and a conduction loss (ON voltage) increases. The ON voltage during this transition period will be referred to as a transient ON voltage.

In the first region 1a, the control gate trench 5b is sandwiched by the active trenches 5a from both sides. By this means, electrons are injected to a portion below the control gate trench 5b which is turned off at an earlier timing and to which electron injection is stopped, from the active trenches 5a on the both sides, so that it is possible to reduce a conduction loss (transient ON voltage). As a result of this, it is possible to sufficiently reduce a loss.

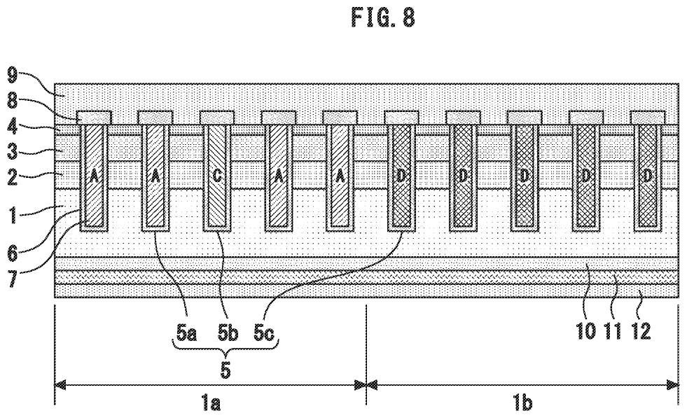

FIG. 8 is a cross-sectional view illustrating a modification of the semiconductor device according to the second embodiment. In the first region 1a, the number of the active trenches Sa is three times or more of the number of the control gate trenches 5b. This increases an amount of electron injection from the active trenches 5a, so that it is possible to further reduce a conduction loss (transient ON voltage).

### Third Embodiment

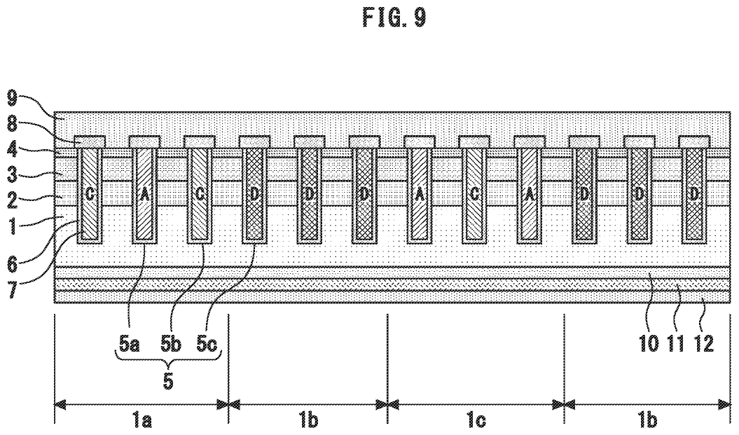

FIG. 9 is a cross-sectional view illustrating a semiconductor device according to a third embodiment. The semiconductor substrate 1 further includes a third region lc. The second region 1b is positioned between the first region 1a and the third region lc. In a similar manner to the first embodiment, in the first region 1a, the active trench 5a and two or more control gate trenches 5b that sandwich the active trench 5a from both sides are formed. On the other hand, in the third region 1c, the control gate trench 5b and two or more active trenches 5a that sandwich the control gate trench 5b from both sides are formed.

There is a trade-off relationship between a conduction loss (transient ON voltage), which can be reduced as a result of carrier density being high, and a turn-off loss, which can be reduced as a result of the carrier density being low, and a ratio of the loss changes in accordance with a drive frequency to be used, and the like. For example, in application at high speed where a ratio of a switching loss is large, emphasis is placed on a turn-off loss, and in application at low speed where a ratio of a conduction loss is large, emphasis is placed on a transient ON voltage. It is therefore preferable to employ a configuration in which a loss ratio between the transient ON voltage and the turn-off loss can be flexibly adjusted in accordance with application. For this, in the present embodiment, it is possible to adjust a loss ratio between the transient ON voltage and the turn-off loss by adjusting an amount of electron injection and a hole discharge amount by adjusting a ratio between the number of the first regions 1a and the number of the third regions 1c. In FIG. 9, a ratio between the number of the first regions 1a and the number of the third regions 1c is set at 1:1, and thus, the transient ON voltage becomes lower than in a case where only the first region 1a is provided.

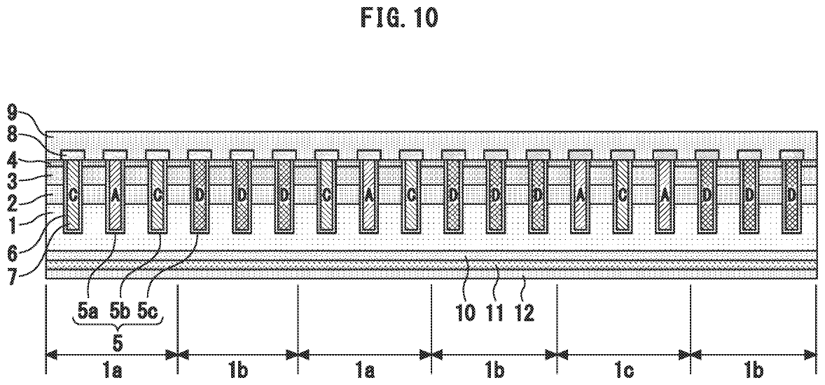

FIG. 10 is a cross-sectional view illustrating a first modification of the semiconductor device according to the third embodiment. A ratio between the number of the first regions 1a and the number of the third regions 1c is adjusted to be 2:1 so as to reduce a turn-off loss. Note that the ratio may be adjusted to be 1:2 so as to reduce a transient ON voltage. While a range of the ratio is described as 1:2 to 2:1, the range is not limited to this and, for example, an adjustment range can be further extended by extending the range to 1:5 to 5:1.

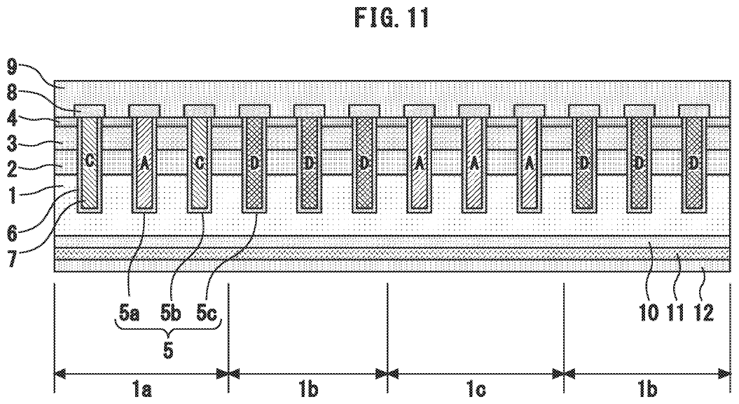

FIG. 11 is a cross-sectional view illustrating a second modification of the semiconductor device according to the third embodiment. Three or more trenches 5 are formed in the third region 1c, and these include one or more active trenches 5a and 0 or one or more control gate trench 5b. A ratio of the active trenches 5a in the trenches 5 formed in the third region 1c is larger than a ratio of the active trenches 5a in the trenches 5 formed in the first region 1a. This can increase an amount of electron injection in a period after the gate electrode 7 in the control gate trench 5b is turned off, so that the loss ratio between the transient ON voltage and the turn-off loss can be adjusted so as to reduce the transient ON voltage.

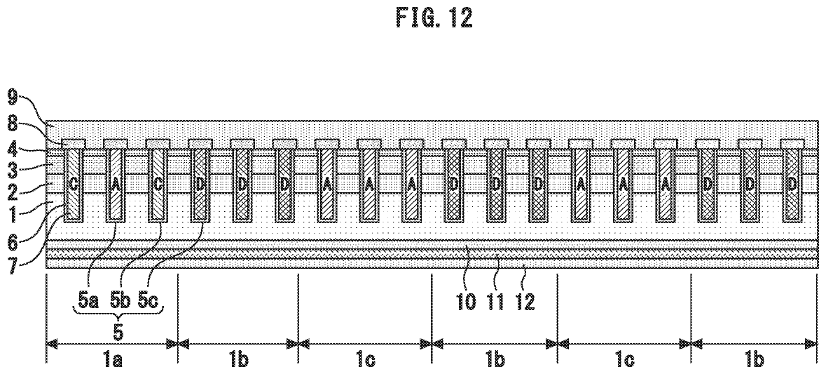

FIG. 12 is a cross-sectional view illustrating a third modification of the semiconductor device according to the third embodiment. While the ratio between the number of the first regions 1a and the number of the third regions 1c is set at 1:1 in FIG. 11, the ratio may be adjusted to be 1:2 so as to further reduce the transient ON voltage as in FIG. 12. The ratio is not limited to these, and by adjusting the ratio as appropriate, a reduction rate of the transient ON voltage can be adjusted.

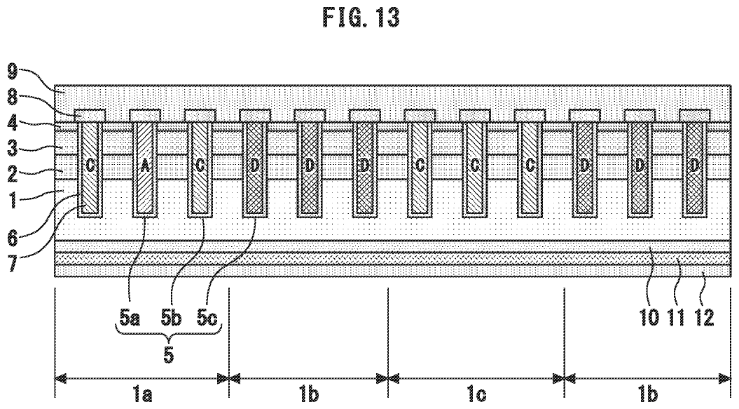

FIG. 13 is a cross-sectional view illustrating a fourth modification of the semiconductor device according to the third embodiment. Only one or more control gate trenches 5b are formed in the third region 1c as the trenches 5. This can enhance a hole discharge effect and can adjust the loss ratio between the transient ON voltage and the turn-off loss so as to reduce the turn-off loss.

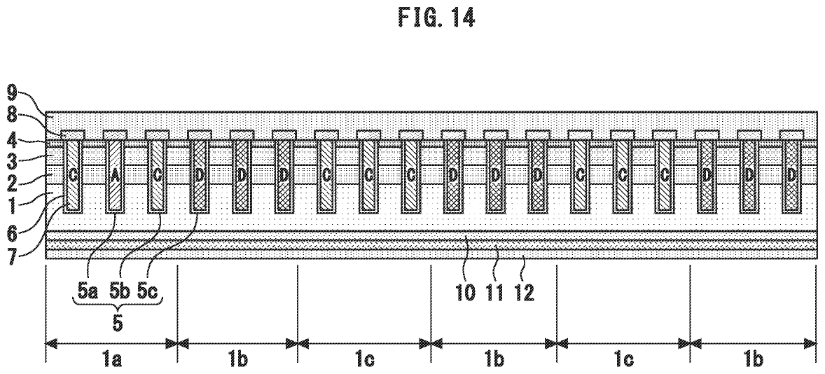

FIG. 14 is a cross-sectional view illustrating a fifth modification of the semiconductor device according to the third embodiment. While a ratio between the number of the first regions 1a and the number of the third regions 1c is set at 1:1 in FIG. 13, the ratio may be adjusted to be 1:2 so as to further reduce the turn-off loss as in FIG. 14. The ratio is not limited to these, and by adjusting the ratio as appropriate, a reduction rate of the turn-off loss can be adjusted.

### Fourth Embodiment

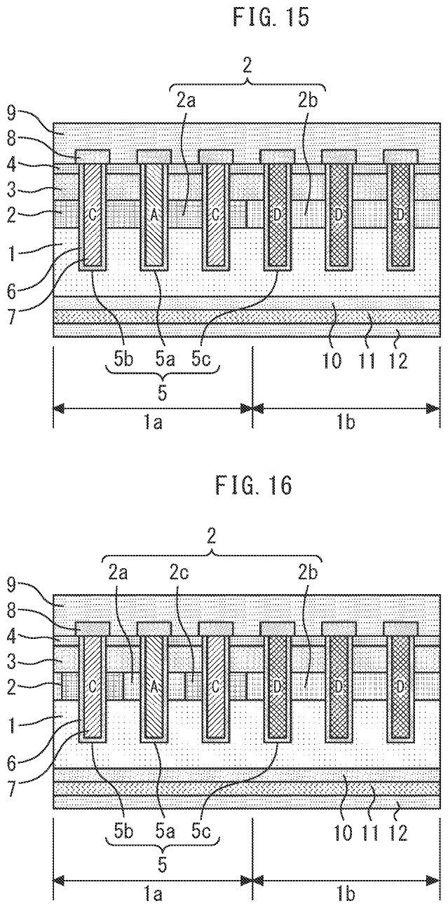

FIG. 15 is a cross-sectional view illustrating a semiconductor device according to a fourth embodiment. In the present embodiment, the impurity concentration of an n-type carrier accumulation layer 2a in the first region 1a in which a channel is to be formed is higher than the impurity concentration of an n-type carrier accumulation layer 2b in the second region 1b in which a channel is not to be formed. An amount of electron injection from the active trench 5a and the control gate trenches 5b can be increased, and a hole discharge amount from the second region 1b can be increased, so that trade-off between the ON voltage and the turn-off loss can be improved. Other configurations and effects are similar to those in the first embodiment, and the like.

FIG. 16 is a cross-sectional view illustrating a modification of the semiconductor device according to the fourth embodiment. In a case where an amount of electron injection is large in turn-on, change in a current over time becomes large, and electromagnetic irradiation noise is generated. Thus, the impurity concentration of an n-type carrier accumulation layer 2c in contact with the control gate trenches 5b that are turned on at a later timing is made higher than the impurity concentration of the n-type carrier accumulation layer 2a in contact with the active trench 5a that is turned on at an earlier timing and affects the change in the current over time. This can reduce the ON voltage without increasing the change in the current over time. It is therefore possible to improve trade-off between the electromagnetic irradiation noise and the ON voltage.

### Fifth Embodiment

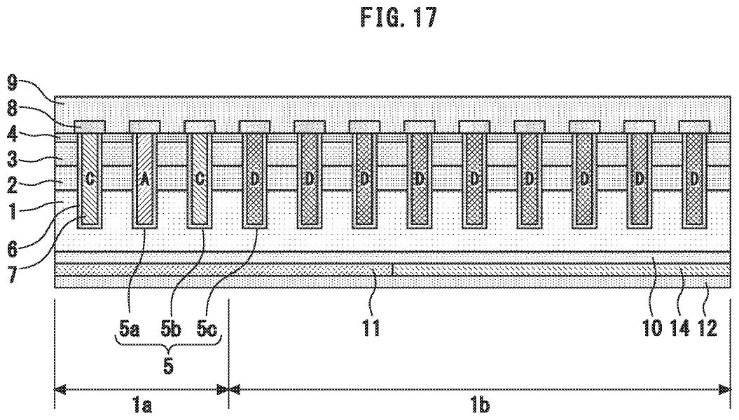

FIG. 17 is a cross-sectional view illustrating a semiconductor device according to a fifth embodiment. While the semiconductor devices according to the first to the fourth embodiments are IGBTs, the semiconductor device in the present embodiment is an RC-IGBT. An n-type cathode layer 14 is formed on the lower surface side of the semiconductor substrate 1. Hole density can be reduced by turning on the gate electrodes 7 in the active trench 5a or the control gate trenches 5b before recovery operation of a diode to inject electrons, so that a recovery loss can be reduced. Other configurations and effects are similar to those in the first embodiment, and the like.

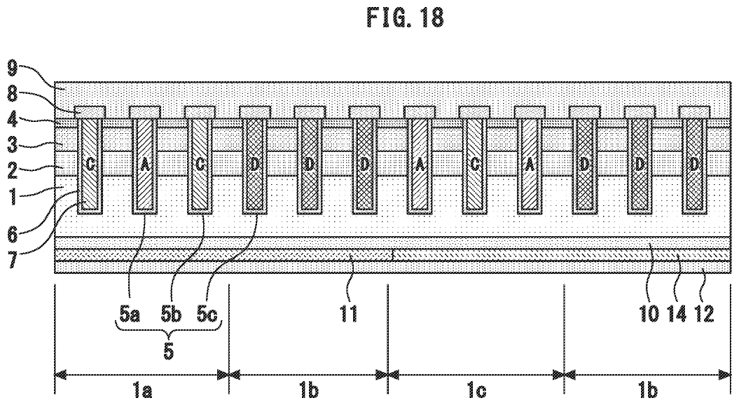

FIG. 18 is a cross-sectional view illustrating a modification of the semiconductor device according to the fifth embodiment. While the n-type cathode layer 14 is formed in the second region 1b in FIG. 17, the n-type cathode layer 14 may be formed in the second region 1b and the third region 1c as illustrated in FIG. 18.

The semiconductor substrate 1 is not limited to a substrate formed of silicon, but instead may be formed of a wide-bandgap semiconductor having a bandgap wider than that of silicon. The wide-bandgap semiconductor is, for example, a silicon carbide, a gallium-nitride-based material, Ga₂O₃ or diamond. A semiconductor device formed of such a wide-bandgap semiconductor has a high voltage resistance and a high allowable current density, and thus can be miniaturized. The use of such a miniaturized semiconductor device enables the miniaturization and high integration of the semiconductor module in which the semiconductor device is incorporated. Further, since the semiconductor device has a high heat resistance, a radiation fin of a heatsink can be miniaturized and a water-cooled part can be air-cooled, which leads to further miniaturization of the semiconductor module. Further, since the semiconductor device has a low power loss and a high efficiency, a highly efficient semiconductor module can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### Supplementary Note 1

A semiconductor device comprising:
a semiconductor substrate of a first conductive type having a first region and a second region which are adjacent to each other;
a base layer of a second conductive type formed on an upper surface side of the semiconductor substrate;
a source layer of the first conductive type formed on an upper surface side of the base layer;
a plurality of gate electrodes respectively formed via gate insulator films inside a plurality of trenches penetrating the source layer and the base layer from the upper surface side of the semiconductor substrate;
an emitter electrode formed on the upper surface of the semiconductor substrate;
a collector layer of the second conductive type formed on a lower surface side of the semiconductor substrate; and
a collector electrode formed on the lower surface of the semiconductor substrate,
wherein the trench in the first region includes a first trench, and two or more second trenches that sandwich the first trench from both sides,
the gate electrodes formed in the two or more second trenches are connected to each other and are not connected to the gate electrode formed in the first trench,
the gate electrode formed in the trench in the second region is connected to the emitter electrode, and
the base layer is connected to the emitter electrode in a region between the first region and the second region.

### Supplementary Note 2

The semiconductor device according to Supplementary Note 1, further comprising a control unit turning off the gate electrode in a control gate trench at a timing earlier than a timing for the gate electrode in an active trench,
wherein the first trench is the active trench, and
the second trench is the control gate trench.

### Supplementary Note 3

The semiconductor device according to Supplementary Note 2, wherein the number of the control gate trenches is three times or more of the number of the active trenches in the first region.

### Supplementary Note 4

The semiconductor device according to Supplementary Note 1, further comprising a control unit turning on the gate electrode in a control gate trench at a timing later than a timing for the gate electrode in an active trench,
wherein the first trench is the active trench, and
the second trench is the control gate trench.

### Supplementary Note 5

The semiconductor device according to Supplementary Note 1, further comprising a control unit turning off the gate electrode in a control gate trench at a timing earlier than a timing for the gate electrode in an active trench,
wherein the first trench is the control gate trench, and
the second trench is the active trench.

### Supplementary Note 6

The semiconductor device according to Supplementary Note 5, wherein the number of the active trenches is three times or more of the number of the control gate trenches in the first region.

### Supplementary Note 7

The semiconductor device according to any one of Supplementary Notes 2 to 4, wherein the semiconductor substrate has a third region,
the second region is positioned between the first region and the third region, and
the control gate trench and two or more active trenches that sandwich the control gate trench from both sides are formed in the third region.

### Supplementary Note 8

The semiconductor device according to any one of Supplementary Notes 2 to 6, wherein the semiconductor substrate has a third region,
the second region is positioned between the first region and the third region, and
a ratio of the active trenches in the trenches formed in the third region is larger than a ratio of the active trenches in the trenches formed in the first region.

### Supplementary Note 9

The semiconductor device according to any one of Supplementary Notes 2 to 6, wherein the semiconductor substrate has a third region,
the second region is positioned between the first region and the third region, and
one or more control gate trenches are formed in the third region.

### Supplementary Note 10

The semiconductor device according to any one of Supplementary Notes 1 to 9, wherein the number of the trenches included in the second region is equal to or larger than the number of the trenches included in the first region.

### Supplementary Note 11

The semiconductor device according to any one of Supplementary Notes 1 to 10, further comprising a carrier accumulation layer of the first conductive type formed below the base layer.

### Supplementary Note 12

The semiconductor device according to Supplementary Note 11, wherein an impurity concentration of the carrier accumulation layer in the first region is higher than an impurity concentration of the carrier accumulation layer in the second region.

### Supplementary Note 13

The semiconductor device according to Supplementary Note 4, further comprising a carrier accumulation layer of the first conductive type formed below the base layer,
wherein an impurity concentration of the carrier accumulation layer in contact with the control gate trench is higher than an impurity concentration of the carrier accumulation layer in contact with the active trench.

### Supplementary Note 1

The semiconductor device according to any one of Supplementary Notes 1 to 13, wherein the semiconductor device is an RC-IGBT.

### Supplementary Note 15

The semiconductor device according to any one of Supplementary Notes 1 to 14, wherein the semiconductor substrate is made of a wide-band-gap semiconductor.

### REFERENCE SIGNS LIST

1 semiconductor substrate; 1a first region; 1b second region; 1c third region; 2 n-type carrier accumulation layer; 3 p-type base layer; 4 n⁺-type source layer; 5 trench; 5a active trench; 5b control gate trench; 6 gate insulator film; 7 gate electrode; 9 emitter electrode; 11 p-type collector layer; 12 collector electrode; 13 control unit

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2023-135870, filed on Aug. 23, 2023 including specification, claims, drawings and summary, on which the convention priority of the present application is based, is incorporated herein by reference in its entirety.

1. A semiconductor device comprising:
a semiconductor substrate of a first conductive type having a first region and a second region which are adjacent to each other;
a base layer of a second conductive type formed on an upper surface side of the semiconductor substrate;
a source layer of the first conductive type formed on an upper surface side of the base layer;
a plurality of gate electrodes respectively formed via gate insulator films inside a plurality of trenches penetrating the source layer and the base layer from the upper surface side of the semiconductor substrate;
an emitter electrode formed on the upper surface of the semiconductor substrate;
a collector layer of the second conductive type formed on a lower surface side of the semiconductor substrate; and
a collector electrode formed on the lower surface of the semiconductor substrate,
wherein the trench in the first region includes a first trench, and two or more second trenches that sandwich the first trench from both sides,
the gate electrodes formed in the two or more second trenches are connected to each other and are not connected to the gate electrode formed in the first trench,
the gate electrode formed in the trench in the second region is connected to the emitter electrode, and
the base layer is connected to the emitter electrode in a region between the first region and the second region.

2. The semiconductor device according to claim 1, further comprising a control unit turning off the gate electrode in a control gate trench at a timing earlier than a timing for the gate electrode in an active trench,
wherein the first trench is the active trench, and
the second trench is the control gate trench.

3. The semiconductor device according to claim 2, wherein the number of the control gate trenches is three times or more of the number of the active trenches in the first region.

4. The semiconductor device according to claim 1, further comprising a control unit turning on the gate electrode in a control gate trench at a timing later than a timing for the gate electrode in an active trench,
wherein the first trench is the active trench, and
the second trench is the control gate trench.

5. The semiconductor device according to claim 1, further comprising a control unit turning off the gate electrode in a control gate trench at a timing earlier than a timing for the gate electrode in an active trench,
wherein the first trench is the control gate trench, and
the second trench is the active trench.

6. The semiconductor device according to claim 5, wherein the number of the active trenches is three times or more of the number of the control gate trenches in the first region.

7. The semiconductor device according to claim 2, wherein the semiconductor substrate has a third region,
the second region is positioned between the first region and the third region, and
the control gate trench and two or more active trenches that sandwich the control gate trench from both sides are formed in the third region.

8. The semiconductor device according to claim 2, wherein the semiconductor substrate has a third region,
the second region is positioned between the first region and the third region, and
a ratio of the active trenches in the trenches formed in the third region is larger than a ratio of the active trenches in the trenches formed in the first region.

9. The semiconductor device according to claim 2, wherein the semiconductor substrate has a third region,
the second region is positioned between the first region and the third region, and
one or more control gate trenches are formed in the third region.

10. The semiconductor device according to claim 1, wherein the number of the trenches included in the second region is equal to or larger than the number of the trenches included in the first region.

11. The semiconductor device according to claim 1, further comprising a carrier accumulation layer of the first conductive type formed below the base layer.

12. The semiconductor device according to claim 11, wherein an impurity concentration of the carrier accumulation layer in the first region is higher than an impurity concentration of the carrier accumulation layer in the second region.

13. The semiconductor device according to claim 4, further comprising a carrier accumulation layer of the first conductive type formed below the base layer,
wherein an impurity concentration of the carrier accumulation layer in contact with the control gate trench is higher than an impurity concentration of the carrier accumulation layer in contact with the active trench.

14. The semiconductor device according to claim 1, wherein the semiconductor device is an RC-IGBT.

15. The semiconductor device according to claim 1, wherein the semiconductor substrate is made of a wide-band-gap semiconductor.
